(19) United States
(12) Patent Application Publication
(10) Pub. No.: US 2016/0133441 A1
(43) Pub. Date: May 12, 2016

(54) ETCH ENHANCEMENT VIA CONTROLLED INTRODUCTION OF CHAMBER CONTAMINANTS

(71) Applicant: APPLIED MATERIALS, INC., Santa Clara, CA (US)

(72) Inventors: JONATHAN GERMAIN, San Francisco, CA (US); JEREMIAH T. P. PENDER, San Jose, CA (US); SHI WEI TOH, Singapore (SG); DAVID T. OR, Santa Clara, CA (US)

(21) Appl. No.: 14/535,997

(22) Filed: Nov. 7, 2014

(51) Int. Cl. H01J 37/32; C23C 16/50; C23C 16/455

(52) U.S. Cl. CPC H01J 37/3244; C23C 16/455; H01J 37/32009; C23C 16/50

(57) ABSTRACT

Embodiments of methods for removing materials from a substrate are provided herein. In some embodiments, a method of controlling contaminants in a process chamber may include flowing a first gas into the process chamber during an interval between completion of a process and start of a subsequent process in the process chamber to remove the contaminants from the process chamber; and flowing a second gas into the process chamber at a specific flow rate during the subsequent process to generate a same species as the contaminants.

### FIELD

Embodiments of the present disclosure generally relate substrate processing systems and, more particularly, to etch chambers used to remove materials from substrates.

### BACKGROUND

Some process chambers for etching or removing material from a substrate rely on cyclical processes to provide reduced damage or damage-free etching and material removal. These cyclical processes typically have two primary phases: a treatment phase, where material on a substrate is selectively modified, and a removal phase, where chemicals are used to selectively remove materials that have been modified during the treatment phase or to selectively remove materials that have not been modified by the treatment phase.

The inventors have observed that these process chambers include various surfaces, including liners, which dynamically adsorb and desorb various contaminants during the removal phase. Specifically, the inventors have observed that contaminants may adsorb onto the surface of the chamber during the removal phase and then desorb during the treatment phase. The inadvertent introduction of these contaminants into the treatment phase can produce variation in the desired chemistry in the treatment phase or changes the way in which dissociation takes place within the plasma during the treatment phase, each of which can undesirably alter process results. The inventors have further observed that the presence of the contaminants also leads to a first-cycle effect (i.e., a difference in process results between a first cycle in a process chamber and subsequent cycles performed in the same process chamber).

The quantity of chemicals that adsorb or desorb is a function of many variables, including the state and age of the chamber, whether the chamber has been exposed to oxygen, and the like. Because the impurities present can have a significant effect on the process results, the processes are unstable from day-to-day and/or from week-to-week. For example, one or more of the removal depth or the removal selectivity of the material to be removed to the remaining materials may vary from day-to-day and/or from week-to-week.

Thus, the inventors have provided improved methods for etching materials.

### SUMMARY

Embodiments of methods for removing materials from a substrate are provided herein. In some embodiments, a method of controlling contaminants in a process chamber includes flowing a first gas into the process chamber during an interval between completion of a process and start of a subsequent process in the process chamber to remove the contaminants from the process chamber; and flowing a second gas into the process chamber at a specific flow rate during the subsequent process to generate a same species as the contaminants.

In some embodiments, a method of selectively removing material disposed on a substrate using a process chamber includes (a) carrying out a plasma based surface activation phase in the process chamber to modify topmost layers of a material disposed on the substrate; (b) carrying out a selective removal phase to selectively remove the modified topmost layers of the material disposed on the substrate or unmodified material disposed on the substrate; (c) flowing a first gas into the process chamber during an interval between completion of the selective removal phase and start of a subsequent plasma based surface activation phase in the process chamber to remove contaminants from the process chamber; (d) carrying out the subsequent plasma based surface activation phase in the process chamber to further modify the material disposed on the substrate while flowing a second gas into the process chamber at a specific flow rate to generate a same species as the contaminants; (e) carrying out another selective removal phase in the process chamber to either selectively remove the further modified material or selectively remove further unmodified material disposed on the substrate; and repeating (c), (d), and (e) until a desired amount of the treated material or the unmodified material is removed.

In some embodiments, a method of controlling selective removal of material disposed on a substrate using a process chamber includes (a) treating a material disposed on the substrate in the process chamber; (b) introducing a first gas and ammonia (NH₃) into the chamber during activation of a plasma; and (c) selectively removing the treated material or unmodified material disposed on the substrate in the process chamber using the plasma.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. It is to be noted, however, that the appended drawings illustrate only typical embodiments of this disclosure and are therefore not to be considered limiting of its scope, for the disclosure may admit to other equally effective embodiments.

FIG. 1 is a flow diagram showing an example of a method of controlling contaminants in a process chamber in accordance with some embodiments of the disclosure.

FIG. 2 is a is a flow diagram showing an example of a method of controlling selective removal of material disposed on a substrate using a process chamber in accordance with some embodiments of the disclosure.

FIG. 3 depicts a schematic side view of a process chamber suitable for performing methods in accordance with the present disclosure.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of methods for removing materials from a substrate are provided herein. The inventive embodiments may advantageously reduce processing variation and thus enhance uniformity of process results from substrate to substrate in a two phase etch process (e.g., an etch process comprising a treatment phase and a removal phase).

In some embodiments, the process chamber may be flushed with a target gas mixture after the removal phase to remove contaminants generated during the removal phase that cause process non-uniformities. In some embodiments, one or more contaminant-generating gases may be introduced in a known quantity, such as at a specific flow rate, to generate the same species of contaminants in a controlled manner during the next treatment phase. The controlled introduction of contaminant species advantageously impacts the removal rate of material during the subsequent removal phase. The controlled introduction of contaminant species may also advantageously maintain more consistent process parameters over time, such as one or more of V_{DC}, removal rate, selectivity of one film over another film, and the like, or may also advantageously drive the selectivity of one film over another.

In some embodiments, small quantities of ammonia (NH₃) gas may be provided into the chamber in addition to an inert gas (such as argon) used during plasma activation for the removal phase. The addition of the ammonia (NH₃) gas advantageously may increase the removal rate during the removal phase. The addition of the ammonia (NH₃) gas advantageously may provide more consistent process parameters over time, such as one or more of V_{DC}, removal rate, selectivity, and the like.

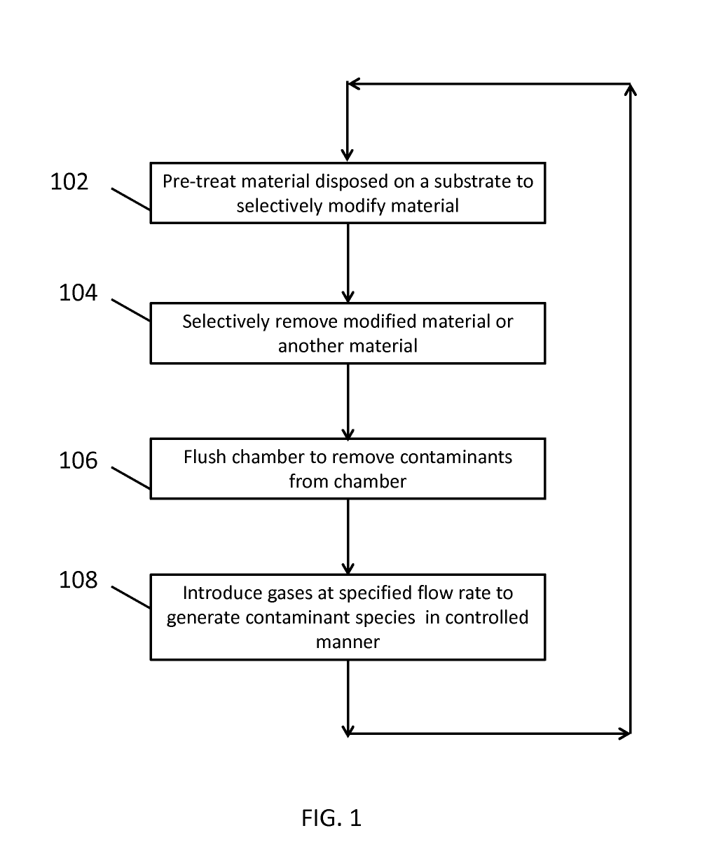

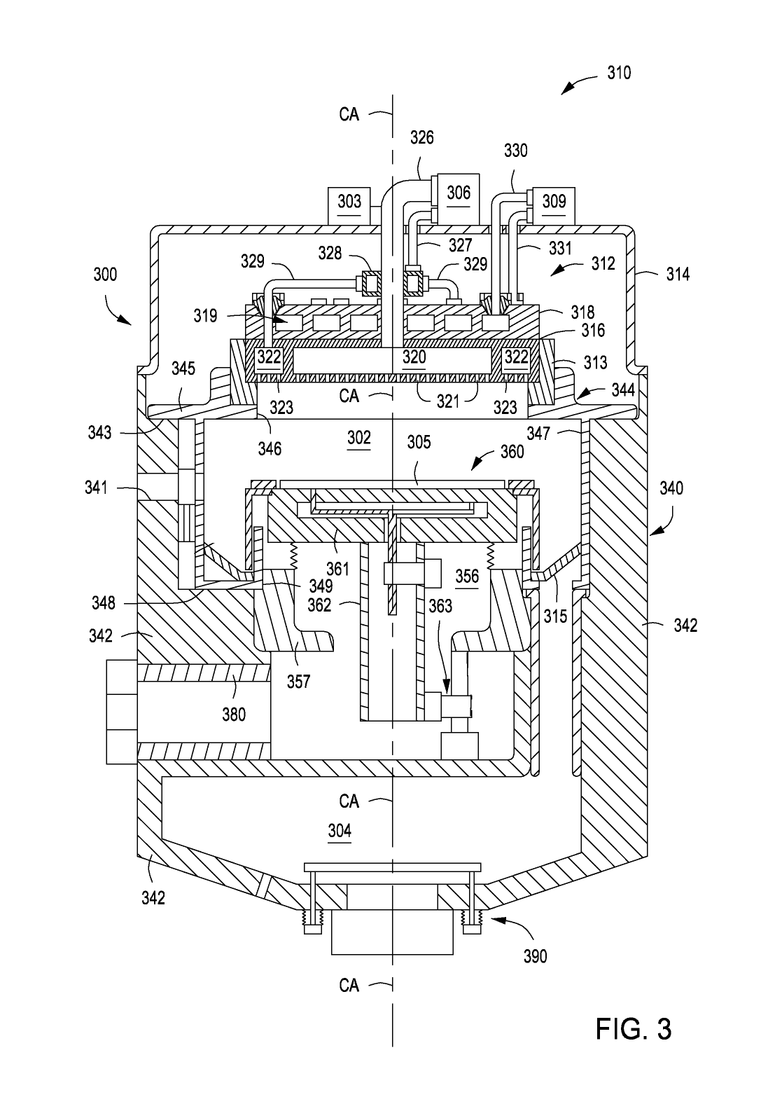

FIG. 1 shows an example of a method of controlling selective removal of material disposed on a substrate using a process chamber, such as the process chamber shown in FIG. 3 and later described herein. At 102, during a first phase of a two-phase process, also referred to herein as a treatment phase, material disposed on a substrate may be treated to selectively modify the material. For example, the treatment phase may be carried out using a plasma process, such as plasma based surface activation, which results in a physical or chemical modification of the topmost molecular layers of the material while maintaining the properties of the bulk material. For example, only horizontal surfaces may be modified by the plasma process.

At 104, during a second phase of the two-phase process, the physically or chemically modified topmost molecular layers of material may be removed during a removal phase. For example, an etchant gas may selectively adsorb onto the treated surface of the material and may form an etch byproduct on the treated surface. The etchant gas may be any mixture of NHxFy, hydrogen fluoride (HF), or other fluorine containing species. The etch byproduct may be ammonium hexafluorosilicate and water ((NH₄)2SiF₆:H₂O). The etchant gas may be formed in a chamber separate from the process chamber in which precursors of the etchant gas may be supplied and a plasma is generated to react with the precursors and form the etchant gas. In some embodiments, the topmost molecular layers of another, unmodified material may be reacted with an etchant gas during the removal phase to form the etch byproduct instead of the modified material. The etch byproduct may then be removed by rapid thermal annealing.

In current processes, the two-phase process may be repeated until a desired thickness of, or all of, the modified or unmodified material is removed. However, contaminants may be formed in the process chamber during the removal phase 104 which may affect a subsequent treatment phase 102. For example, the contaminants in the process chamber may increase the plasma VDC or cause the VDC to vary throughout the subsequent treatment phase.

The concentration of contaminants in the process chamber may change after each iteration of the two-phase process. The concentration of contaminants in the process chamber may also change over time as the process chamber is used each day and may cause the results of the two-phase process to change over time. For example, the removal depth, the electrical characteristics of the removed material, or the removal selectivity of the two-phase process may vary from day-to-day or from week-to-week.

The inventors have determined that flushing the process chamber with a target gas mixture during the interval between the completion of the removal phase 104 and the start of the next treatment phase 102 may remove from the process chamber contaminants formed during the removal phase 104 and may reduce or eliminate the inconsistencies described above. At 106, the process chamber may be flushed of contaminants in this manner. The target gas mixture may include argon or helium, and the target gas mixture may be flowed at 1000 sccm for 10 to 30 seconds at a pressure of 800 mT.

The presence of the contaminants in the process chamber, however, also increases the removal rate during each removal phase 104, though in an inconsistent manner as the concentration of contaminants changes. Thus, the removal of these contaminants in the process chamber may significantly reduce the removal rate.

The inventors have determined that intentionally introducing one or more contaminant-generating gases in a known quantity, such as at a specific flow rate, after flushing the process chamber causes the generation of the contaminant or contaminant-like species in a controlled manner during the next treatment phase. The controlled generation of contaminants increases the removal rate of the removal phase in a controlled manner. Moreover, by introducing the one or more contaminant-generating gases in a controlled manner after each flushing of the process chamber, the same concentration of contaminants may be present during each iteration of the treatment and removal phases so that a consistent VDC, removal rate, selectivity and other process parameters are maintained over time. At 108, the contaminant-generating gases may be introduced into the process chamber after 106 is carried out. For example, the contaminant-generating gases may be one or more of nitrogen trifluoride (NF₃), ammonia (NH₃), or hydrogen (H₂) introduced at a specific flow rate of at least about 0.10% and at most about 4%.

The sequence of the two-phase process 102 and 104, the flushing of the process chamber 106, and the controlled introduction of the one or more contaminant-generating gases 108 may be repeated until a desired quantity or thickness of removed material is either removed or remains.

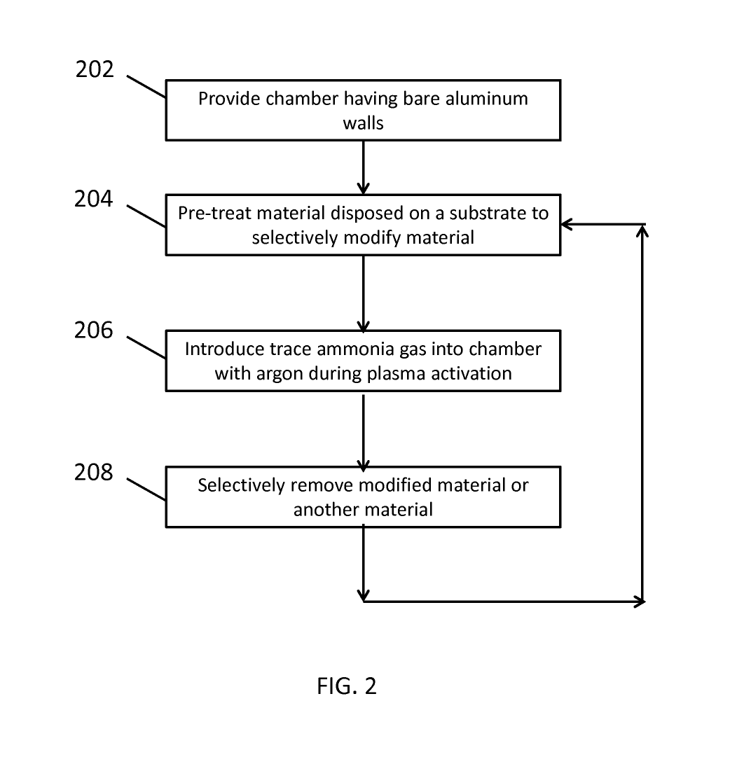

FIG. 2 shows an example of a method of controlling the two-phase process described above using a process chamber, such as using the process chamber shown in FIG. 3 and later described herein.

The inventors have determined that wafer-to-wafer inconsistencies in etch rate may be more controllable, such as by the addition of a gas mixture described herein, when a process chamber having bare inner walls is used in place of the more typical a process chamber in which the inner walls have an anodized aluminum coating or an in-situ coating such as tetraethylorthosilicate (TEOS). The etch rate may be affected by the amount of outgassing from the chamber walls, and the anodized coating may adsorb process gases and subsequently outgas the adsorbed gases in a manner that is more difficult to control than outgassing from bare inner walls. At 202, a process chamber, such as the process chamber shown in FIG. 3 and later described herein, is provided that has bare inner walls.

At 204, a treatment phase of a two-phase process may be carried out. The treatment phase may be performed in the manner described above regarding step 102 of FIG. 1.

The inventors have determined that increasing the flow of argon during the plasma activation for the removal phase of the two-phase process may reduce the amount of outgassing from the chamber walls and may provide a more stable etch rate. However, the increased flow of argon also reduces the etch rate during the removal phase. The inventors therefore determined that in addition to the increased flow of argon, the introduction of trace quantities of ammonia (NH₃) gas into the chamber during plasma activation increases the removal rate during the removal phase. For example, NH₃ may be added at 10 sccm flow rate, and the argon may be flowed at 2000 sccm. At 206, the trace amount of ammonia gas and the increased argon flow may be provided in the manner described above.

At 208, the removal phase is carried out. The removal phase may be performed in the manner described above regarding step 104 of FIGS. 1.

204, 206 and 208 may then be repeated until a desired quantity or thickness of etched material is either removed or remains.

FIG. 3 depicts a schematic diagram of an illustrative plasma process chamber 300 of the kind that may be used to practice embodiments of the disclosure as discussed herein. The plasma process chamber 300 may be utilized alone or, more typically, as a processing module of an integrated semiconductor substrate processing system, or cluster tool, such as a CENTURA® integrated semiconductor substrate processing system, available from Applied Materials, Inc. of Santa Clara, Calif.

The plasma processing chamber 300 may be a plasma etch chamber, a plasma enhanced chemical vapor deposition chamber, a physical vapor deposition chamber, a plasma treatment chamber, an ion implantation chamber, or other suitable vacuum processing chamber. The plasma processing chamber 300 generally includes a chamber lid assembly 310, a chamber body assembly 340, and an exhaust assembly 390, which collectively enclose a processing region 302 and an evacuation region 304. In practice, processing gases may be introduced into the processing region 302 and ignited into a plasma using RF power. A substrate 305 is positioned on a substrate support assembly 360 and exposed to the plasma generated in the processing region 302 to perform a plasma process on the substrate 305, such as etching, chemical vapor deposition, physical vapor deposition, implantation, plasma annealing, plasma treating, abatement, or other plasma processes. Vacuum is maintained in the processing region 302 by the exhaust assembly 390, which removes spent processing gases and byproducts from the plasma process through the evacuation region 304.

The chamber lid assembly 310 generally includes an upper electrode 312 (or anode) isolated from and supported by the chamber body assembly 340 and a chamber lid 314 enclosing the upper electrode 312. The upper electrode 312 is coupled to an RF power source 303 via a conductive gas inlet tube 326. The conductive gas inlet tube 326 is coaxial with a central axis (CA) of the chamber body assembly 340 so that both RF power and processing gases may be symmetrically provided. The upper electrode 312 includes a showerhead plate 316 attached to a heat transfer plate 318.

The showerhead plate 316 has a central manifold 320 and one or more outer manifolds 322. The one or more outer manifolds 322 circumscribe the central manifold 320. The central manifold 320 receives processing gases from a gas source 306 through the gas inlet tube 326 and distributes the received processing gases into a central portion of the processing region 302 through a plurality of gas passages 321. The outer manifold(s) 322 receives processing gases, which may be the same or a different mixture of gases received in the central manifold 320, from the gas source 306. The outer manifold(s) 322 then distributes the received processing gases into an outer portion of the processing region 302 through a plurality of gas passages 323. The manifolds 320, 322 have sufficient volume to function as a plenum so that uniform pressure is provided to each gas passage 321 associated with a respective manifold 320, 322.

A processing gas from the gas source 306 is delivered through an inlet tube 327 into a ring manifold 328 concentrically disposed around the gas inlet tube 326. From the ring manifold 328, the processing gas is delivered through a plurality of gas tubes 329 to the outer manifold(s) 322. In one embodiment, the ring manifold 328 includes a recursive gas path to assure that gas flows equally from the ring manifold 328 into the gas tubes 329.

A heat transfer fluid is delivered from a fluid source 309 to the heat transfer plate 318 through a fluid inlet tube 330. The fluid is circulated through one or more fluid channels 319 disposed in the heat transfer plate 318 and returned to the fluid source 309 via a fluid outlet tube 331.

The chamber body assembly 340 includes a chamber body 342. The substrate support assembly 360 is centrally disposed within the chamber body 342 and positioned to support the substrate 305 in the processing region 302 symmetrically about the central axis (CA).

An upper liner assembly 344 is disposed within an upper portion of the chamber body 342 circumscribing the processing region 302. The upper liner assembly 344 shields the upper portion of the chamber body 342 from the plasma in the processing region 302 and is removable to allow periodic cleaning and maintenance. In one embodiment, the upper liner assembly 344 is temperature controlled, such as by an AC heater (not shown) in order to enhance the thermal symmetry within the chamber and symmetry of the plasma provided in the processing region 302.

The chamber body 342 includes a ledge 343 that supports an outer flange 345 of the upper liner assembly 344. An inner flange 346 of the upper liner assembly 344 supports the upper electrode 312. An insulator 313 is positioned between the upper liner assembly 344 and the upper electrode 312 to provide electrical insulation between the chamber body assembly 340 and the upper electrode 312.

The upper liner assembly 344 includes an outer wall 347 attached to the inner and outer flanges (346,345), a bottom wall 348, and an inner wall 349. The outer wall 347 and inner wall 349 may be substantially vertical, cylindrical walls. The outer wall 347 is positioned to shield chamber body 342 from plasma in the processing region 302, and the inner wall 349 is positioned to at least partially shield the side of the substrate support assembly 360 from plasma in the processing region 302. The bottom wall 348 joins the inner and outer walls (349, 347).

The processing region 302 is accessed through a slit valve tunnel 341 disposed in the chamber body 342 that allows entry and removal of the substrate 305 into/from the substrate support assembly 360. The upper liner assembly 344 has a slot 350 disposed therethrough that matches the slit valve tunnel 341 to allow passage of the substrate 305 therethrough.

The substrate support assembly 360 generally includes lower electrode 361 (or cathode) and a hollow pedestal 362, the center of which the central axis (CA) passes through, and is supported by a central support member 357 disposed in the central region 356 and supported by the chamber body 342. The central axis (CA) also passes through the center of the central support member 357. The lower electrode 361 is coupled to the RF power source 303 through a matching network (not shown) and a cable (not shown) routed through the hollow pedestal 362. When RF power is supplied to the upper electrode 312 and the lower electrode 361, an electrical field formed therebetween ignites the processing gases present in the processing region 302 into a plasma.

The central region 356 is sealed from the processing region 302 and may be maintained at atmospheric pressure, while the processing region 302 is maintained at vacuum conditions.

An actuation assembly 363 is positioned within the central region 356 and attached to the chamber body 342 and/or the central support member 357 to raises or lowers the pedestal 362. Since the lower electrode 361 is supported by the pedestal 362, the actuation assembly 363 provides vertical movement of the lower electrode 361 relative to the chamber body 342, the central support member 357, and the upper electrode 312. In addition, since the substrate 305 is supported by the lower electrode 361, the gap between the substrate 305 and the showerhead plate 316 may also be varied, resulting in greater control of the process gas distribution across the substrate 305.

In one embodiment, the lower electrode 361 is an electrostatic chuck, and thus includes one or more electrodes (not shown) disposed therein. A voltage source (not shown) biases the one or more electrodes with respect to the substrate 305 to create an attraction force to hold the substrate 305 in position during processing. Cabling coupling the one or more electrodes to the voltage source is routed through the hollow pedestal 362 and out of the chamber body 342 through one of the plurality of access tubes 380.

A conductive, slant mesh liner 315 is positioned in a lower portion of the upper liner assembly 344. The slant mesh liner 315 may have a plurality of apertures formed there through to allow exhaust gases to be drawn uniformly therethrough, which in turn, facilitates uniform plasma formation in the processing region 302 and allows greater control of the plasma density and gas flow in the processing region 302.

The disclosure may be practiced using other semiconductor substrate processing systems wherein the processing parameters may be adjusted to achieve acceptable characteristics by those skilled in the art by utilizing the teachings disclosed herein without departing from the spirit of the disclosure.

While the foregoing is directed to embodiments of the present disclosure, other and further embodiments of the disclosure may be devised without departing from the basic scope thereof.

1. A method of controlling contaminants in a process chamber, comprising:
flowing a first gas into the process chamber during an interval between completion of a process and start of a subsequent process in the process chamber to remove the contaminants from the process chamber; and
flowing a second gas into the process chamber at a specific flow rate during the subsequent process to generate a same species as the contaminants.

2. The method claim 1, wherein the process and the subsequent process are each two-phase processes having similar first stages and similar second stages.

3. The method claim 2, wherein the second gas is flowed into the process chamber during a first phase of the subsequent process.

4. The method claim 2, wherein the first phase of each two-phase process includes a treatment phase in which a material disposed on a substrate is modified.

5. The method claim 4, wherein the treatment phase modifies topmost molecular layers of the material.

6. The method claim 4, wherein the treatment phase includes plasma based surface activation of topmost molecular layers of the material.

7. The method claim 4, wherein a second phase of each two-phase process includes selective removal of one of the modified material or unmodified material disposed on the substrate.

8. The method claim 1, wherein the first gas includes argon or helium.

9. The method claim 1, wherein the first gas is flowed at 1000 sccm for 10 to 30 seconds.

10. The method claim 1, wherein the second gas is at least one of nitrogen trifluoride (NF₃), ammonia (NH₃), or hydrogen (H₂).

11. The method claim 1, wherein the specific flow rate of the second gas is at least about 0.10% and at most about 4%.

12. A method of selectively removing material disposed on a substrate using a process chamber, comprising:
(a) carrying out a plasma based surface activation phase in the process chamber to modify topmost layers of a material disposed on the substrate;
(b) carrying out a selective removal phase to selectively remove the modified topmost layers of the material disposed on the substrate or unmodified material disposed on the substrate;
(c) flowing a first gas into the process chamber during an interval between completion of the selective removal phase and start of a subsequent plasma based surface activation phase in the process chamber to remove contaminants from the process chamber;
(d) carrying out the subsequent plasma based surface activation phase in the process chamber to further modify the material disposed on the substrate while flowing a second gas into the process chamber at a specific flow rate to generate a same species as the contaminants;
(e) carrying out another selective removal phase in the process chamber to either selectively remove the further modified material or selectively remove further unmodified disposed on the substrate; and
repeating (c), (d), and (e) until a desired amount of the modified material or the unmodified material is removed.

13. A method of controlling selective removal of material disposed on a substrate using a process chamber, comprising:
(a) treating a material disposed on the substrate in the process chamber;
(b) introducing a first gas and ammonia (NH₃) into the chamber during activation of a plasma; and
(c) selectively removing the treated material or unmodified material disposed on the substrate in the process chamber using the plasma.

14. The method claim 13, wherein the first gas includes argon.

15. The method claim 13, wherein the first gas is introduced into the chamber at a 2000 sccm flow rate.

16. The method claim 13, wherein the NH₃ is introduced into the chamber at a 10 sccm flow rate.

17. The method claim 13, wherein inner walls of the process chamber are bare aluminum.

18. The method claim 13, wherein treating the material modifies topmost layers of the material.

19. The method claim 13, wherein treating the material includes plasma based surface activation of topmost layers of the material.

20. The method claim 13, further comprising
repeating (a), (b), and (c) until a desired amount of the treated material or the unmodified material is removed.
